(19) United States
(12) Patent Application Publication
(10) Pub. No.: US 2009/0296444 A1
(43) Pub. Date: Dec. 3, 2009

(54) MEMORY MODULE AND METHOD FOR ACCESSING MEMORY MODULE

(76) Inventor: Chih-Hui Yeh, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/128,622

(22) Filed: May 29, 2008

(51) Int. Cl. G11C 5/02; G11C 8/00

(52) U.S. Cl. 365/51; 365/233.1

(57) ABSTRACT

A memory module includes a plurality of memory sub-modules and a plurality of groups of input pins, where each memory module includes a plurality of memory chips and the memory chips are series-connected. In addition, the plurality of groups of input pins are connected to the plurality of memory modules, respectively, and are utilized to receive the same input signals, where each group of input pins includes a plurality of input pins which are utilized to transmit the input signals to a corresponding memory module.

### BACKGROUND OF THE INVENTION

1. Field of the Invention

The present invention relates to a memory module, and more particularly, to a memory module capable of improving rising/falling time of input signals and increasing setup/hold time, and a method for accessing the memory module.

2. Description of the Prior Art

Please refer to FIG. 1. FIG. 1 is a diagram illustrating a prior art dual in-line memory module (DIMM) 100. As shown in FIG. 1, the DIMM 100 comprises eight memory chips 110₁₃ 1-110_8, where each memory chip comprises twenty-nine input pins. Regarding the operations of the DIMM 100, as shown in FIG. 1, twenty-nine input signals are generated from a controller 120 and are inputted into the memory chip 100_1 through input pins (not shown), then the input signals sequentially transmit to the memory chip 110_2, 110_3, . . . , 110_8. However, the rising time and falling time of the input signals of the later-stage memory chips (e.g., 110_7 and 110_8) will increase due to the signal attenuation effect from an equivalent RLC (resistor/inducer/capacitor) of the earlier-stage memory chips, causing lessened setup time and hold time of the input signals. Please refer to FIG. 2. FIG. 2 is an eye pattern of the input signals of the memory chips 110_1-110_8. As shown in FIG. 2, the later-stage memory chips have a narrower eye width, and particularly, the eye width of the last memory chip 110_8 is 919 pico-seconds (ps), and is much lower than the eye width of the memory chip 110_1 (1057 ps). Therefore, when the input signals with a higher frequency are inputted into the back-end memory chip(s), the setup time may not be sufficient and this results in unstable signals, further causing a higher error rate of the data interpretation.

### SUMMARY OF THE INVENTION

It is therefore an objective of the present invention to provide a memory module capable of improving rising/falling time of input signals and increasing setup/hold time and to provide a method for accessing the memory module, to solve the above-mentioned problems.

According to one embodiment of the present invention, a memory module is provided. The memory module comprises a plurality of memory sub-modules and a plurality of groups of input pins, where each memory module comprises a plurality of memory chips and the memory chips are connected in series. In addition, the plurality of groups of input pins are respectively connected to the plurality of memory modules and are utilized to receive the same input signals, where each group of input pins is utilized to transmit the input signals to a corresponding memory module. Each group of input pins comprises twenty-nine input pins, and the twenty-nine input pins are utilized for receiving two clock signals, sixteen memory address input signals, three bank address input signals, a chip-select signal, a row address strobe signal, a column address strobe signal, a write enable signal, an on-die termination signal, a clock enable signal (CKE), a calibration signal (ZQ), and a reset signal.

According to another embodiment of the present invention, a memory module is provided. The memory module comprises a plurality of memory sub-modules and a plurality of groups of input pins, where each memory module comprises a plurality of memory chips and the memory chips are series-connected. In addition, the plurality of groups of input pins are respectively connected to the plurality of memory modules and are utilized to receive the same input signals, where each group of input pins is utilized to transmit the input signals to a corresponding memory module. Each group of input pins comprises at least nineteen input pins, and the nineteen input pins are utilized for receiving at least six row address signals, at least five column address signals, a row address chip-select signal, a column address chip-select signal, two clock signals, an on-die termination signal, a clock enable signal (CKE), a calibration signal (ZQ), and a reset signal.

According to another embodiment of the present invention, a method for accessing a memory module is provided. The method comprises: positioning a plurality of memory sub-modules in the memory module, wherein each memory sub-module comprises a plurality of memory chips and the plurality of memory chips are series-connected; positioning a plurality of groups of input pins in the memory module, and each group of input pins is utilized for receiving a same plurality of input signals; and transmitting the plurality of input signals into a corresponding memory sub-module. The input signals comprise two clock signals, sixteen memory address input signals, three bank address input signals, a chip-select signal, a row address strobe signal, a column address strobe signal, a write enable signal, an on-die termination signal, a clock enable signal (CKE), a calibration signal (ZQ), and a reset signal.

According to another embodiment of the present invention, a method for accessing a memory module is provided. The method comprises: positioning a plurality of memory sub-modules in the memory module, wherein each memory sub-module comprises a plurality of memory chips and the plurality of memory chips are series-connected; positioning a plurality of groups of input pins in the memory module, and each group of input pins is utilized for receiving a same plurality of input signals; and transmitting the plurality of input signals into a corresponding memory sub-module. The input signals comprise at least nineteen input pins, and the nineteen input pins are utilized for receiving at least six row address signals, at least five column address signals, a row address chip-select signal, a column address chip-select signal, two clock signals, an on-die termination signal, a clock enable signal (CKE), a calibration signal (ZQ), and a reset signal.

According to the memory module and the method for accessing the memory module provided by the present invention, the rising/falling time and the setup/hold time of the input signals can be improved, and can further reduce the error rate of data interpretation.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a prior art dual in-line memory module.

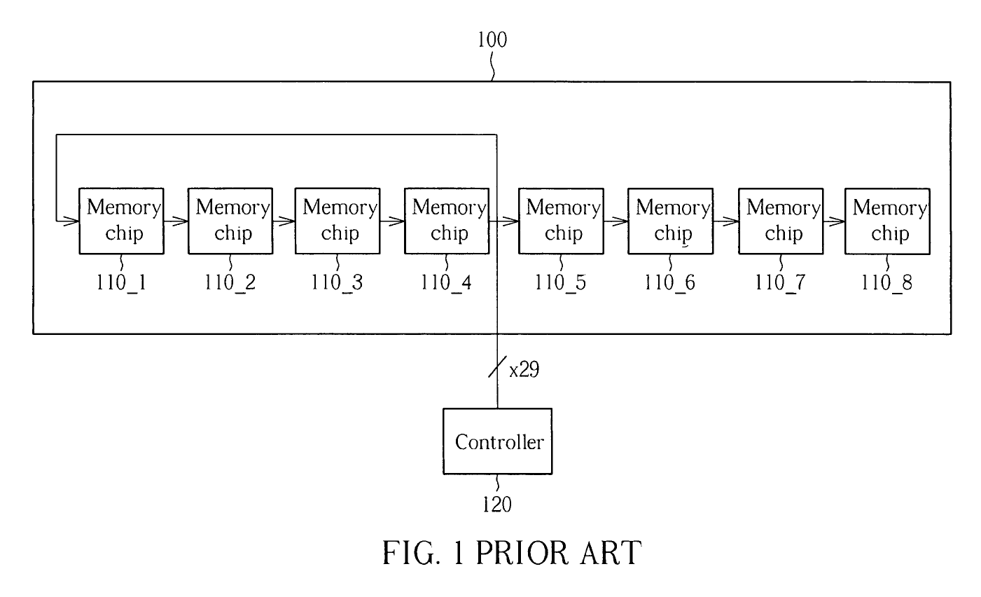

FIG. 2 is an eye pattern of the input signals of the memory chips shown in FIG. 1.

FIG. 3 is a diagram illustrating a memory module according to one embodiment of the present invention.

FIG. 4 is a diagram illustrating a memory module according to another embodiment of the present invention.

FIG. 5 is a diagram illustrating six row address signals according to one embodiment of the present invention.

FIG. 6 is a diagram illustrating five column address signals according to one embodiment of the present invention.

### DETAILED DESCRIPTION

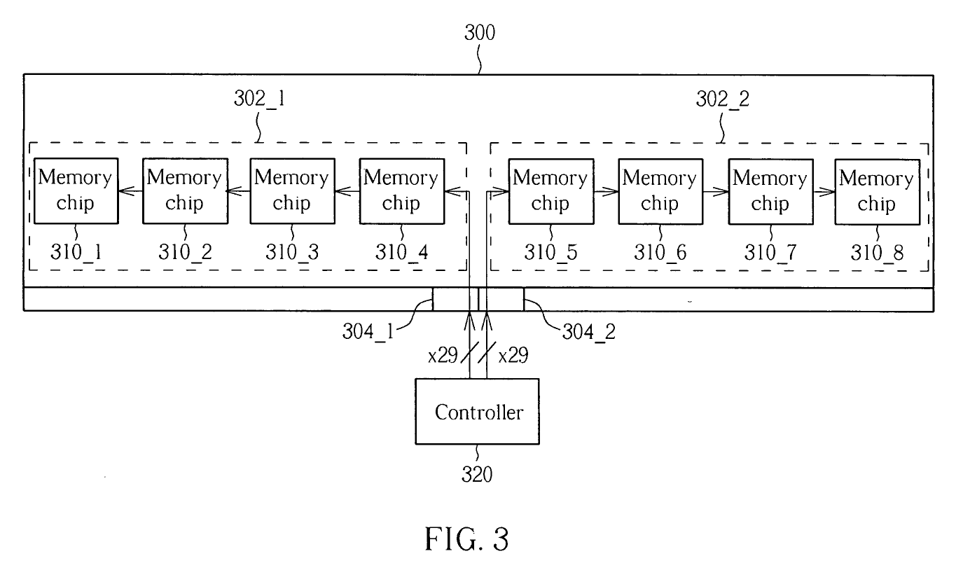

Please refer to FIG. 3. FIG. 3 is a diagram illustrating a memory module according to one embodiment of the present invention. As shown in FIG. 3, the memory module 300 comprises (but is not limited to) two memory sub-modules 302_1 and 302_2, a first group of input pins 304_1 and a second group of input pins 304_2, where the memory sub-module 302_1 comprises a plurality of memory chips 301_1-310_4 and the memory sub-module 302_2 comprises a plurality of memory chips 301_5-310_8. Each memory chip includes twenty-nine input pins, and the memory chips 310_1-310_4 are connected in series, as are memory chips 310_5-310_8. In addition, the first group and the second group of input pins 304_1 and 304_2 each includes twenty-nine input pins, and are respectively connected to the memory chips 310_4 and 310_5.

Regarding the operations of the memory module 300, as shown in FIG. 3, a first group of input signals is generated from a controller 320, and is inputted into the memory chip 310_4 through the first group of input pins 304_1, then first group of input signals sequentially transmits to the memory chips 310_3, 310_2, and 310_1. Similarly, a second group of input signals is also generated from the controller 320, and is inputted into the memory chip 310_5 through the second group of input pins 304_2, and then the second group of input signals sequentially transmits to the memory chips 310_6, 310_7, and 310_8. The first group of input signals is the same as the second group of input signals, and the first and the second group of input signals each includes twenty-nine input signals, where the twenty-nine input signals includes two clock signals, sixteen memory address input signals, three bank address input signals, a chip-select signal, a row address strobe signal, a column address strobe signal, a write enable signal, a clock enable signal (CKE), an on-die termination (ODT) signal, a calibration signal (ZQ), and a reset signal.

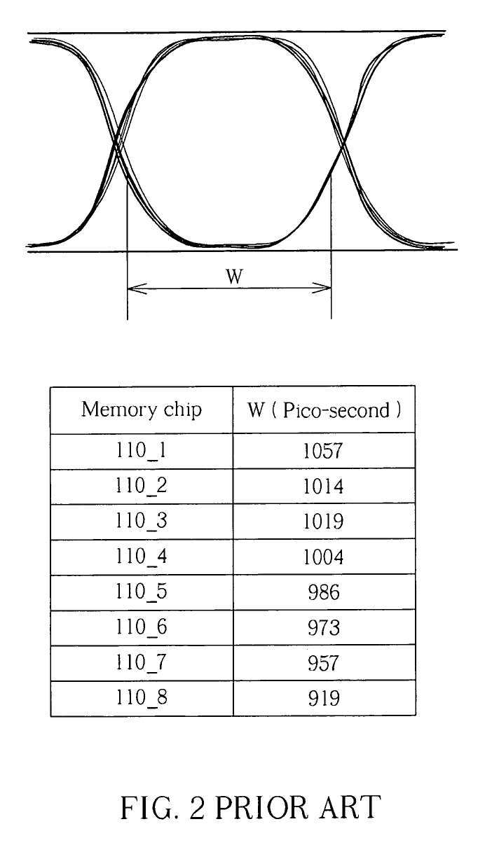

Compared with the DIMM 100, each group of input signals in the memory module 300 transmits only into four memory chips. Taking the measuring results of the DIMM 100 shown in FIG. 2 as an example, the eye widths of the memory chip 310_1 and 310_8 in the memory module 300 are 1004 pico-seconds. Compared with the memory chip 110_8 in the DIMM 100 whose eye width is 919 pico-seconds, the present invention can indeed improve the quality of the input signals of the memory chip, and reduces the error rate of the data interpretation.

Please note that the number of memory sub-modules and the number of groups of input pins are one embodiment of the present invention only. In practice, the number of memory sub-modules and the number of groups of input pins can be varied according to the designer's considerations, and these alternative designs are all within the scope of the present invention.

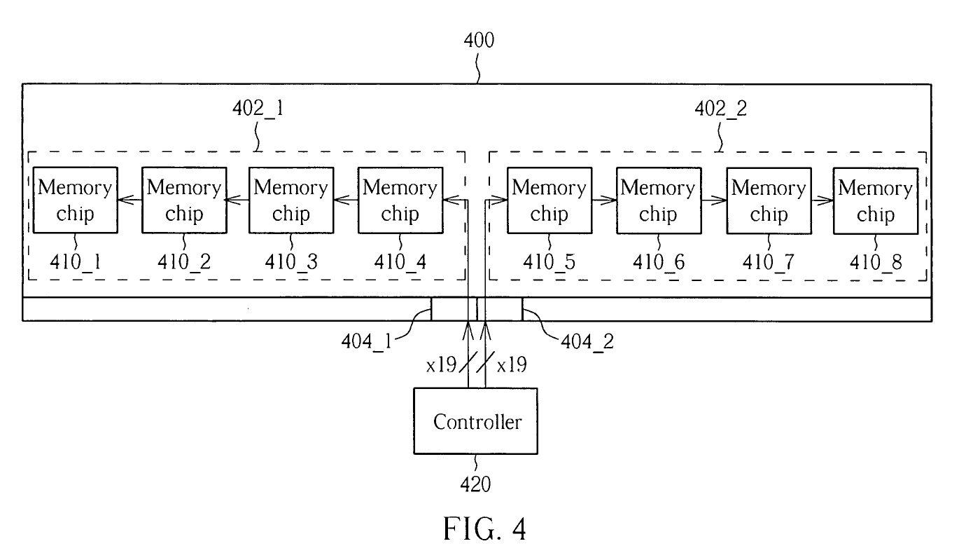

However, although the memory module 300 can improve the quality of the input signals of the memory chip, the memory module 300 must include two groups of input pins; that is, the memory module 300 includes fifty-eight input pins. Therefore, the layout of the DIMM becomes more difficult due to the size limit of the printed circuit board (PCB) of the DIMM. To solve this problem, the present invention further provides a memory module. Please refer to FIG. 4, the memory module 400 comprises two memory sub-modules 402_1 and 402_2, a first group of input pins 404_1 and a second group of input pins 404_2, where the memory sub-module 402_1 comprises a plurality of memory chips 401_1-410_4 and the memory sub-module 402_2 comprises a plurality of memory chips 401_5-410_8. Each memory chip includes nineteen input pins, and the memory chips 410_1-410_4 are connected in series, as are the memory chips 410_5-410_8. In addition, the first group and the second group of input pins 404_1 and 404_2 each includes nineteen input pins, and are respectively connected to the memory chips 410_4 and 410_5. In the present invention, the nineteen input pins includes six row address signal pins, five column address signal pins, a row address chip-select signal pin, a column address chip-select signal pin, two clock signal pins, an on-die termination signal pin, a clock enable signal (CKE), a calibration signal (ZQ), and a reset signal.

Regarding the operations of the memory module 400, as shown in FIG. 4, a first group of input signals is generated from a controller 420, and is inputted into the memory chip 410_4 through the first group of input pins 404_1, then first group of input signals sequentially transmits to the memory chips 410_3, 410_2, and 410_1. Similarly, a second group of input signals is also generated from the controller 420, and is inputted into the memory chip 410_5 through the second group of input pins 404_2, and then second group of input signals sequentially transmits to the memory chips 410_6, 410_7, and 410_8. The first group of input signals is the same as the second group of input signals, and the first and the second group of input signals each includes nineteen input signals. The nineteen input signals includes six row address signals, five column address signals, a row address chip-select signal, a column address chip-select signal, two clock signals, an on-die termination (ODT) signal, a clock enable signal (CKE), a calibration signal (ZQ), and a reset signal.

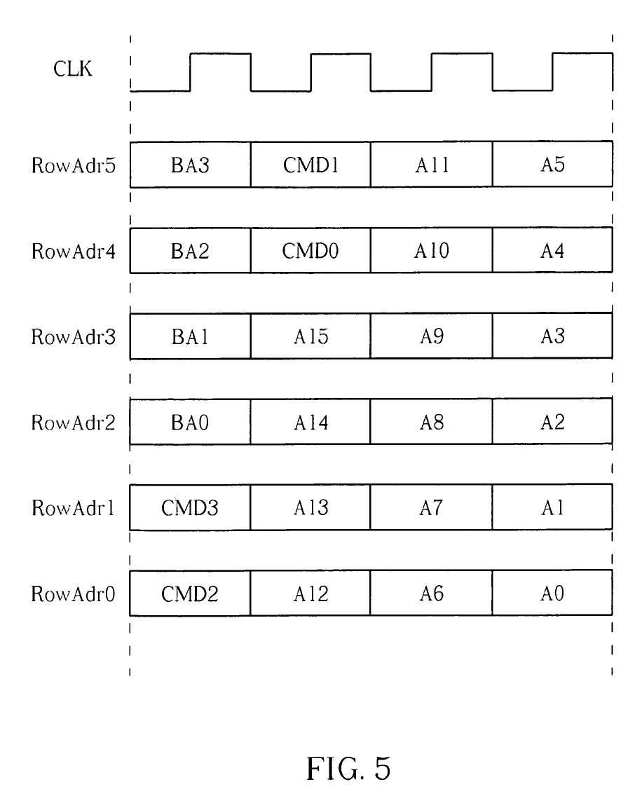

Please refer to FIG. 5. FIG. 5 is a diagram illustrating six row address signals according to one embodiment of the present invention. As shown in FIG. 5, the length of a row address command package of each row address signal (RowAdr0-RowAdr5) corresponds to four clock periods of the clock signal CLK, and the row address command package comprises four row input commands. Therefore, the six row address command packages of the six row address signals comprise twenty-four row input commands in total. In this embodiment, the twenty-four row input commands comprises four pieces of setting information of bank address BA0-BA3, sixteen pieces of setting information of memory address A0-A15, and four pieces of memory control command setting information CMD0-CMD3, where the four pieces of setting information of bank address BA0-BA3 are implemented for replacing the bank address input signals BA0-BA3 in the prior art double data rate (DDR) synchronous DRAM (SDRAM) architecture, and the sixteen pieces of setting information of memory address A0-A15 are implemented for replacing the memory address input signals A0-A15 in the prior art DDR SDRAM architecture. In addition, the four pieces of memory control command setting information CMD0-CMD3 are decoded to generate a control command of a plurality of memory control commands, where the memory control commands may comprise an activate command, a pre-charge command, a refresh command, a mode register set (MRS) command, a self-refresh entry (SRE) command, a power down entry command, a ZQ calibration long/ZQ calibration short (ZQCL/ZQCS) command, etc.

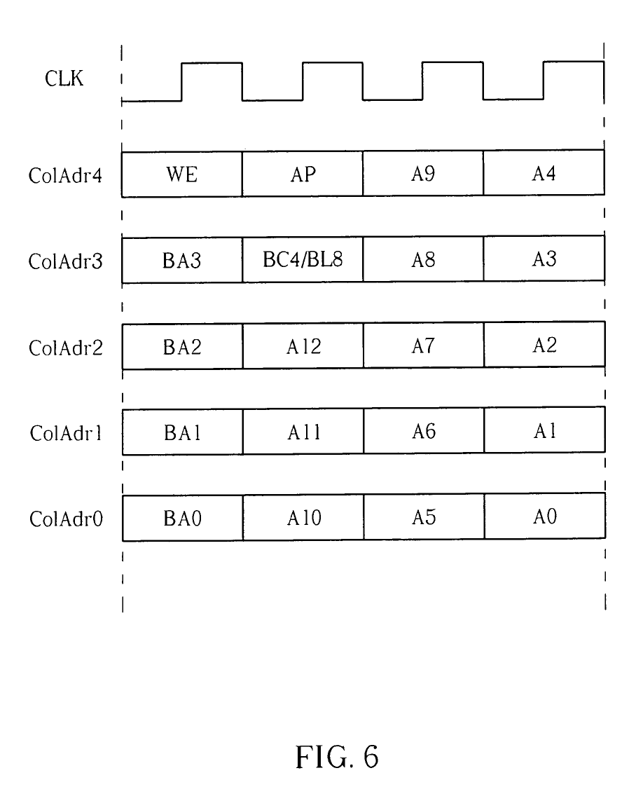

Please refer to FIG. 6. FIG. 6 is a diagram illustrating five column address signals according to one embodiment of the present invention. As shown in FIG. 6, the length of a column address command package of each column address signal (ColAdr0-ColAdr4) corresponds to four clock periods of the clock signal CLK, and the column address command package comprises four column input commands. Therefore, the five column address command packages of the five column address signals comprise twenty column input commands in total. The twenty column input commands comprise four pieces of setting information of bank address BA0-BA3, thirteen pieces of setting information of memory address A0-A12, a write enable (WE) input command, an auto-pre-charge (AP) input command, and a burst chop 4/burst length 8 (BC4/BL8) input command. The four pieces of setting information of bank address BA0-BA3 are implemented for replacing the bank address input signals BA0-BA3 in the prior art DDR SDRAM architecture, and the thirteen pieces of setting information of memory address A0-A12 are implemented for replacing the memory address input signals A0-A12 in the prior art DDR SDRAM architecture.

Please note that the input commands of the six row address command packages of the six row address signals are for illustrative purposes only. In practice, the twenty-four row input commands shown in FIG. 5 can be rearranged and the twenty column input commands shown in FIG. 6 can also be rearranged without influencing the operations of the memory chip of the present invention. For example, locations of any two of the row input commands can be exchanged, and the locations of any two of the column input commands can also be exchanged. In another example, locations of the row input commands can be rotated, and locations of the column input commands can be rotated as well. Additionally, the number of the above-mentioned row address signals (RowAdr0-RowAdr5), the number of the above-mentioned column address signals (ColAdr0-ColAdr4), and the number of pieces of the setting information of the bank address (BA0-BA3) are for illustrative purposes only. In practice, when the storage capacity of the memory is increased (e.g., the number of pieces of setting information of the memory address is increased, or the number of the banks is increased), seven or more row address signals can be used, and six or more column address signals can also be used. For example, an added row address signal pin and an added column address signal pin can be added into both the first and the second group of input pins, where the added row address signal pin is utilized to receive a row address signal RowAdr6, the added column address signal pin is utilized to receive a column address signal ColAdr5, a row address command package of the row address signal RowAdr6 comprises two pieces of setting information of the bank address BA4, BA5, and two pieces of setting information of the memory address A16, A17. A column address command package of the column address signal ColAdr5 comprises two pieces of setting information of the bank addresses BA4, BA5, and two pieces of setting information of the memory addresses A13, A14.

In addition, the row address chip-select signal is utilized for enabling the memory chip to receive the row address signals, and the column address chip-select signal is utilized for enabling the memory chip to receive the column address signals. When the row address chip-select signal or the column address chip-select signal is at an enabling state, the memory chip can receive the row address signals or the column address signals.

As mentioned above, each group of input pins in the memory module 400 comprises nineteen input pins. Therefore, the two groups of input pins comprise thirty-eight input pins. Compared with the fifty-eight input pins in the memory module 300 shown in FIG. 3, the memory module 400 can improve the quality of the input signals of the memory chip without increasing by too many input pins, and the layout of the DIMM is easier under the size limit of the PCB.

Those skilled in the art will readily observe that numerous modifications and alterations of the device and method may be made while retaining the teachings of the invention.

What is claimed is:

1. A memory module, comprising:
a plurality of memory sub-modules, wherein each memory sub-module comprises a plurality of memory chips and the plurality of memory chips are connected in series; and
a plurality of groups of input pins, respectively coupled to the plurality of memory sub-modules, for receiving same input signals, wherein each group of input pins is utilized for transmitting the plurality of input signals into the corresponding memory sub-modules.

2. The memory module of claim 1, wherein a quantity of the memory sub-modules and a quantity of input pins are both two.

3. The memory module of claim 1, wherein each group of input pins is connected to only one memory chip in a corresponding memory sub-module.

4. The memory module of claim 1, wherein each group of input pins comprises twenty-nine input pins, and the twenty-nine input pins are utilized for receiving two clock signals, sixteen memory address input signals, three bank address input signals, a chip-select signal, a row address strobe signal, a column address strobe signal, a write enable signal, an on-die termination signal, a clock enable signal (CKE), a calibration signal (ZQ), and a reset signal.

5. The memory module of claim 1, wherein the plurality of input pins comprises:
at least six row address signal pins, for receiving at least six row address signals, wherein a length of a row address command package of each row address signal corresponds to a plurality of clock periods of a clock signal, and the row address command package comprises a plurality of row input commands; and
at least five column address signal pins, for receiving at least five column address signals, wherein a length of a column address command package of each column address signal corresponds to a plurality of clock periods of the clock signal, and the column address command package comprises a plurality of column input commands.

6. The memory module of claim 5, wherein the length of the row address command package and the length of the column address command package correspond to four clock periods, and the row address command package comprises four row input commands, and the column address command package comprises four column input commands.

7. The memory module of claim 6, wherein the row input commands of the at least six row address command packages transmitted by the row address signals comprises at least four pieces of setting information of bank address, sixteen pieces of setting information of memory address, and four pieces of memory control command setting information, and the four pieces of memory control command setting information are utilized to be decoded to generate a memory control command.

8. The memory module of claim 6, wherein the column input commands of the at least five column address command packages transmitted by the five column address signals comprises at least four pieces of setting information of bank address and thirteen pieces of setting information of memory address.

9. The memory module of claim 8, wherein the column input commands of the at least five column address command packages transmitted by the five column address signals comprises at least a write enable input command, an auto pre-charge (AP) input command and a burst chop/burst length (BC/BL) input command.

10. The memory module of claim 5, wherein the plurality of input pins comprises:
a row address chip-select signal pin, for receiving a row address chip-select signal to utilize a memory chip to receive the plurality of row address signals;
a column address chip-select signal pin, for receiving a column address chip-select signal to utilize a memory chip to receive the plurality of column address signals;
two clock signal pins, for receiving two clock signals, respectively;
an on-die termination signal pin, for receiving an on-die termination signal;
a clock enable (CKE) signal pin, for receiving a clock enable signal;
a calibration signal pin, for receiving a calibration signal; and
a set signal pin, for receiving a reset signal.

11. A method for accessing a memory module, comprising:
positioning a plurality of memory sub-modules in the memory module, wherein each memory sub-module comprises a plurality of memory chips and the plurality of memory chips are series-connected;
positioning a plurality of groups of input pins in the memory module, and each group of input pins is utilized for receiving a same plurality of input signals; and
transmitting the plurality of input signals into a corresponding memory sub-module.

12. The method of claim 11, wherein a quantity of the memory sub-modules and a quantity of input pins are both two.

13. The method of claim 11, further comprising:
for each memory sub-module, transmitting a plurality of input signals into a memory chip of the memory sub-module through the corresponding input pins.

14. The method of claim 11, wherein the plurality of input signals comprises twenty-nine input signals, and the twenty-nine input signals comprises two clock signals, sixteen memory address input signals, three bank address input signals, a chip-select signal, a row address strobe signal, a column address strobe signal, a write enable signal, an on-die termination signal, a clock enable signal (CKE), a calibration signal (ZQ), and a reset signal.

15. The method of claim 11, wherein the plurality of input signals comprises:
at least six row address signals, wherein a length of a row address command package of each row address signal corresponds to a plurality of clock periods of a clock signal, and the row address command package comprises a plurality of row input commands; and
at least five column address signals, wherein a length of a column address command package of each column address signal corresponds to a plurality of clock periods of the clock signal, and the column address command package comprises a plurality of column input commands.

16. The method of claim 15, wherein the length of the row address command package and the length of the column address command package correspond to four clock periods, and the row address command package comprises four row input commands, and the column address command package comprises four column input commands.

17. The method of claim 16, wherein the row input commands of the at least six row address command packages of the six row address signals comprises at least four pieces of setting information of bank address, sixteen pieces of setting information of memory address, and four pieces of memory control command setting information, and the four pieces of memory control command setting information are utilized to be decoded to generate a memory control command.

18. The method of claim 16, wherein the column input commands of the at least five column address command packages of the five column address signals comprises at least four pieces of setting information of bank address and thirteen pieces of setting information of memory address.

19. The method of claim 18, wherein the column input commands of the at least five column address command packages of the five column address signals comprises at least a write enable (WE) input command, an auto pre-charge (AP) input command and a burst chop/burst length (BC/BL) input command.

20. The method of claim 15, wherein the plurality of input signals comprises:
a row address chip-select signal, for utilizing a memory chip to receive the plurality of row address signals;
a column address chip-select signal, for utilizing a memory chip to receive the plurality of column address signals;
two clock signals;
an on-die termination signal pin, for receiving an on-die termination signal;
a clock enable (CKE) signal;
a calibration signal; and
a set signal.
